(19) United States
(12) Patent Application Publication
(10) Pub. No.: US 2006/0011324 A1
(43) Pub. Date: Jan. 19, 2006

(54) WOUND, LOUVERED FIN HEAT SINK DEVICE

(76) Inventors: C. James Rogers, Racine, WI (US); Donald Ernst, Lancaster, PA (US); Gregory G. Hughes, Milwaukee, WI (US)

Correspondence Address: WOOD, PHILLIPS, KATZ, CLARK & MORTIMER, 500 W. MADISON STREET, SUITE 3800, CHICAGO, IL, 60661, US

(21) Appl. No.: 10/889,702

(22) Filed: Jul. 13, 2004

(51) Int. Cl. H05K 7/20

(52) U.S. Cl. 165/80.3; 361/704

(57) ABSTRACT

A heat sink device (10,60) is provided for cooling an electronic component (12) having a surface (14) that rejects heat. A fan (22) overlies the surface (14) to direct an airflow (24) towards the surface (14), the fan having a rotational axis (29). The heat sink device includes a fin (26,64,66) wound about a central axis (40) that extends parallel to the rotational axis (29). The fin (26,64,66) includes louvered surfaces that extend parallel to the central axis (40).

### FIELD OF THE INVENTION

This device relates to heat sinks, and in more particular applications to improved fins for heat sink devices that include a fan for cooling an electronic component such as an integrated circuit chip, a CPU chip, a large scale chip package, or a very large scale chip package, especially an impingement airflow fan.

### BACKGROUND OF THE INVENTION

Heat sink devices that include a base plate having one surface adapted for receiving heat from an electronic device and another surface for mounting a heat conductive, serpentine fin, and an impingement airflow fan for directing an air flow perpendicular to the surface of the plate on which the fin is mounted are well known. Examples of such heat sink devices are disclosed in U.S. Pat. Nos. 4,753,290, 5,251,101, 5,299,632, 5,494,098, 5,597,034, 6,109,341, and 6,135,200. Additionally, U.S. Pat. Nos. 6,336,497 and 6,360,816 show examples of similar devices wherein a cylindrical post extends upward from the surface of the plate, with fins wrapped around the post to receive the air flow from the impingement airflow fan. U.S. Pat. No. 6,223,813 discloses a similar heat sink wherein pin fins are wrapped around a cylindrical post.

### SUMMARY OF THE INVENTION

It is the primary object of the invention to provide a new and improved heat sink device.

In accordance with one aspect of the invention, an improvement is provided in a heat sink device for cooling an electronic component having a surface that rejects heat. The heat sink device includes a fan overlying the surface to direct an airflow towards the surface. The fan has a rotational axis. The improvement includes a fin wound about a central axis, the central axis extending parallel to the rotational axis, and the fin including louvered surfaces that extend parallel to the central axis.

In one aspect, the improvement further includes a plate having first and second surfaces, the first surface configured to receive heat rejected from the surface of the electronic component, and the second surface underlying the fan; and a spiral wound fin on the second surface of the plate and underlying the fan, the fin including a strip of metal coiled about the central axis. The strip has the louvers formed therein extending parallel to the central axis between spaced side margins of the strip. In a further aspect, each of the louvers has a louver angle that opens radially outward in a direction of rotation of the fan.

According to one aspect, the improvement further includes an elongate conductive post and at least one serpentine fin. The post includes first and second end surfaces and a circumferential surface extending between the end surfaces parallel to the central axis, the first end surface being configured to receive heat rejected from the surface of the electronic component. The at least one serpentine fin is wrapped around the circumferential surface and has alternating peaks and valleys joined by louvered side walls, each of the peaks and valleys extending generally parallel to the central axis.

In accordance with one aspect of the invention, a heat sink device is provided for cooling an electronic component having a surface that rejects heat. The device includes a plate and a spiral wound fin. The plate has first and second surfaces, with the first surface configured to receive heat rejected from the surface of the electronic component. The spiral wound fin is on the second surface of the plate and includes a strip of metal coiled about an axis extending generally perpendicular to the second surface. The strip has louvers formed therein extending parallel to the axis between spaced side margins of the strip.

In one aspect, each of the louvers of the spiral wound fin has a louver angle, and the louver angles vary as a function of a radial distance from the axis.

According to one aspect, at least one of the side margins includes a plurality of spaced tabs, each of the tabs extending from the strip to engage an adjacent portion of the at least one of the side margins to maintain a desired spacing between adjacent coils of the spiral wound strip. In a further aspect, each of the tabs extends in a radially outward direction from the strip.

In one aspect, the device further includes a wire coiled about the axis and sandwiched between adjacent coils of the strip to maintain a desired spacing between the adjacent coils. In one further aspect, the wire is sandwiched between adjacent portions of one of the side margins. In another aspect, the wire is sandwiched between louvers of adjacent coils of the strip.

In accordance with one aspect, the strip has a width extending parallel to the louvers and the louvers extending over 80% to 95% of the width. In a preferred aspect, the louvers extend over 88% to 93% of the width.

In accordance with one aspect of the invention, a heat sink device is provided for transferring heat from an electronic component to a cooling airflow provided by a fan, with the electronic component having a surface that rejects heat. The heat sink device includes an elongate conductive post and at least one serpentine fin. The elongate conductive post includes first and second end surfaces and a circumferential surface extending between the end surfaces in a direction of elongation of the conductive post. The first end surface is configured to receive heat rejected from the surface of the electronic component. The at least one serpentine fin is wrapped around the circumferential surface and has alternating peaks and valleys joined by louvered side walls, each of the peaks and valleys extending parallel to the direction of elongation.

In one aspect, each of the louvers extends perpendicular to the direction of elongation.

According to one aspect, the at least one serpentine fin has a width extending parallel to the direction of elongation; and the device further includes a shroud covering a radially outermost portion of the at least one serpentine fin and extending over 30% to 60% of the width farthest from the first end surface. In a further aspect the shroud includes a band.

In accordance with one aspect, the device further includes a second serpentine fin wrapped around the circumferential surface between the circumferential surface and the at least one serpentine fin, and having alternating peaks and valleys extending parallel to the direction of elongation and joined by louvered side walls. A separating band is sandwiched between second serpentine fin and the at least one serpentine fin. In a further aspect, the separating band is perforated.

In one aspect, the circumferential surface is cylindrical in shape.

Other objectives, aspects, and advantages will become apparent from a review of the entire specification, including the drawings and appended claims.

### BRIEF DESCRIPTION OF THE DRAWINGS

FIG. 1 is an elevation view of a heat sink device embodying the present invention;

FIG. 2 is a plan view of the heat sink device of FIG. 1;

FIG. 3 is a perspective view of the heat sink device of FIG. 1;

FIG. 4 is an enlarged view of the encircled area marked 4-4 in FIG. 3;

FIGS. 5A and 5B are enlarged, partial views of the encircled area marked 5-5 in FIG. 2 showing alternate embodiments for a fin structure used therein;

FIG. 6 is a side elevation of another heat sink device embodying the invention;

FIG. 7 is a plan view of the device shown in FIG. 6;

FIG. 8 is a perspective view of the device shown in FIG. 6; and

FIG. 9 is an enlarged section view taken from line 9-9 in FIG. 7.

### DETAILED DESCRIPTION OF THE PREFERRED EMBODIMENTS

As seen in FIGS. 1-3, an impingement airflow heat sink device 10 is provided for cooling an electronic component 12, such as for example an integrated circuit, a CPU chip, a large scale chip package, or a very large scale chip package, having a surface 14 that rejects heat. The heat sink device 10 includes a plate 16 having first and second surfaces 18 and 20 with the surface 18 configured to receive heat rejected from the surface 14 electronic component 12; a fan, shown schematically at 22 in FIG. 1 only, overlying the second surface 20 to direct an impingement airflow, shown generally by the arrows 24, toward the second surface 20 substantially perpendicular to the second surface 20; and a louvered fin 26 underlying the fan and bonded to the second surface so as to transfer heat from the plate 16 to the airflow 24 and the environment surrounding the heat sink device 10.

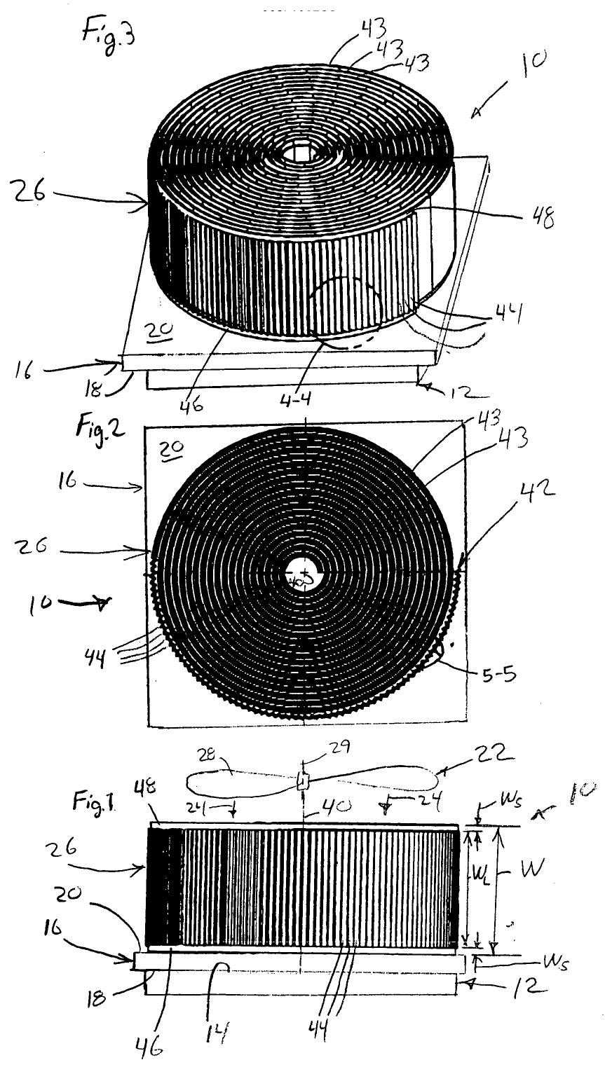

The plate 16 is preferably a solid, one piece construction with the surfaces 18 and 20 being substantially planar and parallel to each other, particularly if the surface 14 of the electronic component 12 is planar. However, it may be advantageous in some applications for at least the surface 18 to have a non-planar configuration if required to conform to a non-planar surface 14 on the electronic component 12. In this regard, the surface 18 will typically be seated against the surface 14 or have a bonding layer or a layer of thermal grease or gel therebetween. However, in some application it may be desirable to space the surface 18 and 14 apart. Further, the plate 16 may serve as a cap or lid for the electronic component 12. Additionally, as an alternative to a solid, one piece construction, the plate 16 could include heat pipes embedded therein, or could be a multi piece, hollow construction forming a planar type heat pipe on the interior of the construction. It should be understood that while the surfaces 20 and 18 are shown as having a square or rectangular shape in FIGS. 2 and 3, this is for purposes of illustration and in some applications other shapes for the surfaces 20 and 18 may be desirable, such as for example, a circular shape that would conform essentially to the outer extent of the fin 26, or other shapes that would conform essentially to the perimeter of the electronic component 12 for the particular application. Preferably, the plate 16 is made from a suitable heat conducting material, such as aluminum, copper or their alloys.

The fan 22 is preferably a so called “impingement” or “pancake” type fan, many suitable types of which are well-known in the industry. Typically, the fan 22 will include a housing (not shown) that rotatably mounts a fan impeller, shown schematically at 28, driven by an electric motor (not shown) about an axis 29 substantially perpendicular to the surface 20. Preferably, the fan 22 is configured to distribute the airflow 24 over as large a portion of the fin 26 as is possible given the packaging restraints for the heat sink device 10. The fan 22 will typically be attached to the remainder of the heat sink device 10 either by a suitable attachment structure that extends past the fin 26 to engage the plate 16 or by bonding the housing of the fan to the fin 26 using a suitable bonding technique, such as epoxy bonding. However, in some applications it may be desirable to mount the fan 22 to other structures associated with the electronic component 12, such as a housing that carries the electronic component 12 and the heat sink device 10. In any event, because the mounting of the fan 22 relative to the remainder of the heat sink device 10 is not critical to the understanding or the function of the heat sink device 10 with respect to the slit fin 26, further description of the various means for mounting the fan 22 will not be provided herein.

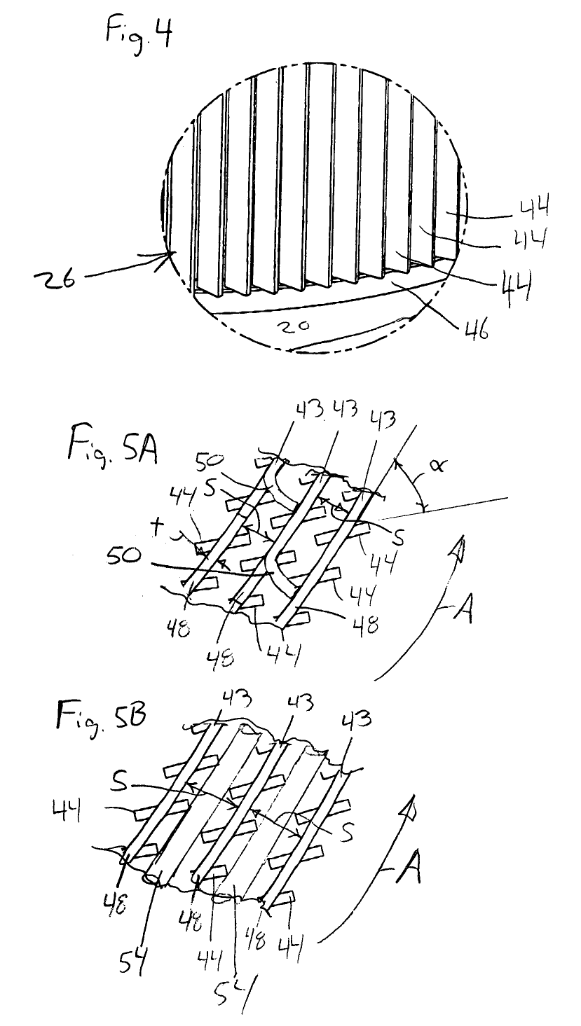

As best seen in FIGS. 2 and 3, the fin 26 is a spiral wound fin that is wound about a central axis 40 extending parallel to the rotational axis 29 and preferably aligned therewith so that the fin 26 is centered on the axis 29. The fin 26 is made from a strip 42 of metal coiled about the axis 40 to define a plurality of coils 43 of the strip 42. The strip 42 has louvers 44, best seen in FIG. 4, formed therein extending parallel (within reasonable manufacturing tolerances) to the axes 29,40 between spaced side margins 46,48 of the strip 42. For purposes of illustration, not all of the louvers 44 are shown in FIGS. 2 and 3, but it should be understood that the louvers 44 preferably extend throughout the entire coiled length of the strip 42. As best seen in FIG. 1, the side margins preferably extend parallel (within reasonable manufacturing tolerances) to the surface 20. As best seen in FIG. 5A, each of the louvers 44 has a louver angle α, which in FIG. 5A is 45°. It should be appreciated that the louver angle α can vary from 90° down to near 0°, depending upon the particular requirements of each application. Furthermore, it should be appreciated that in some applications it will be desirable for all of the louvers 44 to have the same louver angle α, while in other applications it will be desirable to have the louver angle α vary as a function of radial distance from the axis 40, depending upon the particular parameters of each application, such as the particular parameters of the fan 22 and the heat sink device 12. Preferably, as shown in FIG. 5A, the louver angles a open radially outward in the direction of rotation of the fan, shown schematically by arrows A in FIGS. 5A and 5B. However, it should be understood, that in some applications it may be desirable for the louver angles α to open radially outward in the opposite direction of the rotation of the fan.

As best seen in FIG. 1, the strip 42 has a width W extending parallel to the louvers 44. Preferably, the louvers have a width W_{L} that extend over 80% to 95% of the width W, and in highly preferred embodiments, the width W_{L} extends over 88% to 93% of the width W. It is also preferred for the side margins 46 and 48 to have essentially identical widths W_{S} divided from the remainder of the width W not taken up by the louvers 44. However, in some applications, it may be desirable for the side margins 46,48 not to have equal widths W_{S}.

As seen in FIG. 5A, in some embodiments a plurality of spaced tabs 50 can be provided in one or both the side margins 46 and 48, with each of the tabs 50 extending from the strip 42 to engage an adjacent portion of the corresponding side margin 46,48 in an adjacent coil 43 to maintain a desired spacing S between adjacent coils 43 of the spiral wound strip 42. While it is possible for the tabs 50 to extend either radially inward or outward from the strip, FIG. 5A illustrates all of the tabs 50 extending in a radially outward direction from the strip 42.

As seen in FIG. 5B, in some embodiments it may be desirable to maintain the desired spacing S between adjacent coils 43 of the strip 42 by coiling a wire 54 about the axis 40 such that the wire is sandwiched between adjacent coils 43 of the strip 42 to maintain the desired spacing S. The spacing S will be a function of the diameter D of the wire. As seen in FIG. 5B, it is preferable that the wire be sandwiched between the louvers 44 of the adjacent coils 43 of the strip 42. Alternatively, in some embodiments it may be desirable for the wire to be sandwiched between adjacent portions of the side margin 46 adjacent the surface 20 so as not to block the air flow 24 from the fan 22.

The louvers 44 direct the air flow 24 from the fan 22 through the coiled strip 42 to exit the outermost coil 43 after having removed heat from the fin 26 and the plate 16. In this regard, it should be appreciated that the louver angle α will influence the pressure drop through the fin 26 and thus the optimum louver angle(s) α will depend upon fan design and other factors such as louver size, including louver pitch and louver width W_{L}, fin spacing S, fin thickness t, etc.

It should be appreciated that the spiral wound fin 26 can provide a relatively dense configuration of fin surfaces similar to what could be provided by a pin-fin type construction. However, in some applications, such high density may not be desirable.

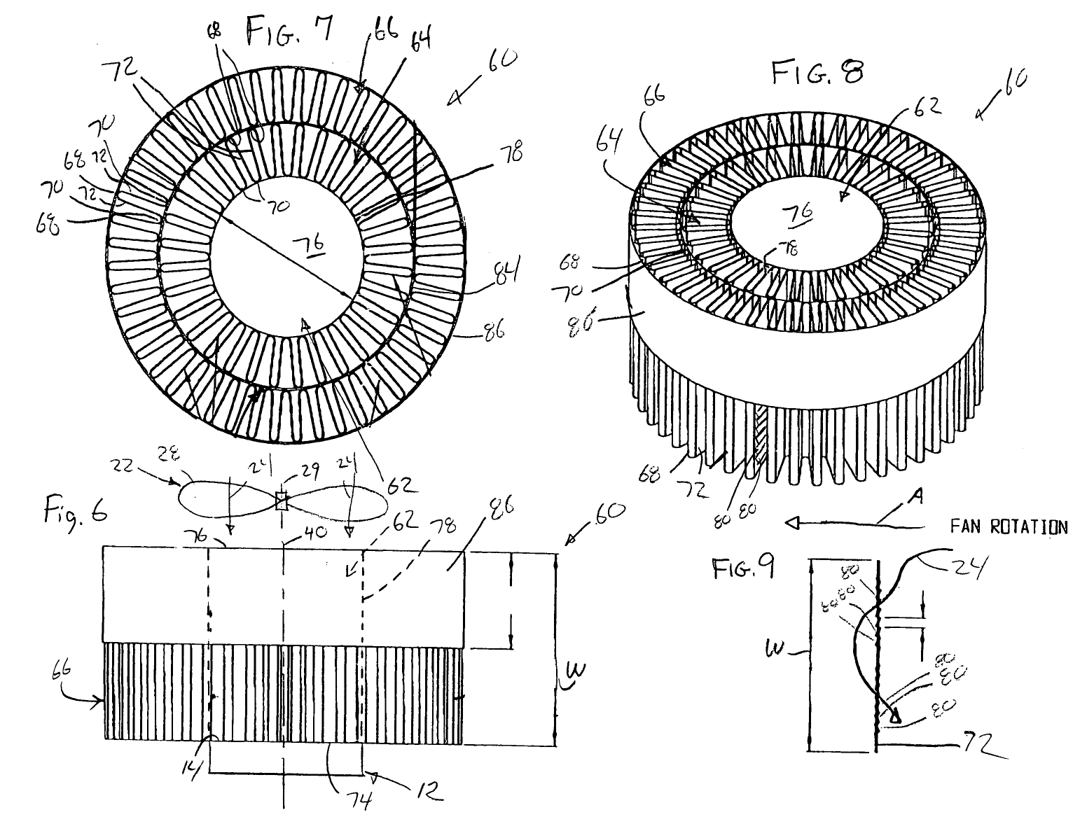

FIGS. 6-9 illustrate another embodiment of a heat sink device 60, with like numbers representing like features. The heat sink device 60 of FIGS. 6-9 differs from the device 10 of FIGS. 1-5B in that the plate 16 has been replaced with a conductive center post 62, and the spiral fin 26 has been replaced by at least one serpentine fin (two serpentine fins 64 and 66 shown in FIGS. 6-9), with each of the fins 64,66 having alternating peaks 68 and valleys 70 joined by louvered side walls 72. For purposes of illustration, louvers are shown only in FIG. 9 and on one of the side walls 72 of FIG. 8. As best seen in FIGS. 6 and 8, the peaks 68 and valleys 70 preferably extend parallel (within reasonable manufacturing tolerances) to the axes 29 and 40. The device 60 of FIGS. 6-9 is similar to the device 10 of FIGS. 1-5B in that the fins 64 and 66 are both wound about the central axis 40 that extends parallel to the rotational axis 29, with the fins 64,66 including louvered surfaces (defined by the side wall 72) that extend parallel (within reasonable manufacturing tolerances) to the central axis 40.

The center post 62 includes a pair of spaced, end surfaces 74 and 76, and a circumferential surface 78 extending between the end surfaces 74,76 in a direction of elongation of the conductive post 62. While it is preferred for the circumferential surface to be cylindrical in shape, in some applications it may be desirable for the circumferential surface to have other shapes. As with the end surface 18, the end surface 74 is configured to receive heat rejected from the surface 14 of the electronic component 12 and is preferably planar. However, again as with the surface 18, it may be advantageous in some applications for the surface 74 to have a nonplanar configuration if required to conform to a nonplanar surface 14 on the electronic component 12. It may be desirable in some applications for the center post 62 to be a solid, one piece construction made of a suitable heat conductive material, such as copper or aluminum. Alternatively, in other applications, it may be desirable for the center post 62 to have heat pipes embedded therein or to be a multi piece, hollow construction that defines a heat pipe in the interior of the construction.

As best seen in FIG. 9, the louvered side walls 72 include a plurality of louvers 80 formed therein, preferably extending between the associated peak 68 and valley 70 perpendicular (within reasonable manufacturing tolerances) to the axes 29 and 40. It should be appreciated that the configuration of the louvers, including the louver pitch, louver angle α, and louver pattern, will be highly dependent upon the parameters of each particular application. FIG. 9 illustrates one possible louver pattern wherein the direction of the air flow 24 tends to be redirected through the side walls 72 by the pattern of the louvers 80, which are angled outwardly in one direction in an upper half of the side wall 72 and then in the opposite direction in the lower half of the side wall 72.

As best seen in FIGS. 7 and 8, if more than one serpentine fin is utilized, it is preferred to provide a separator sheet 84 sandwiched between the fins 64,66, and specifically between the peaks 68 of the fin 64 and the valleys 70 of the fin 66. In some applications, it may be desirable for the sheet 84 to be perforated to allow the air flow 24 to pass through the sheet 84. Similarly, it may be desirable for the sheet to extend over only the upper 30% to 60% of the width W farthest from the surface 74.

As best seen in FIGS. 6-8, in some applications it may be desirable for the device 60 to include a shroud, shown in FIGS. 6-8, in the form of a band 86, covering the radially outermost portion of the outermost fin 66 and extending over 30% to 60% of the width W farthest from the first end 74. In the illustrated embodiment, the shroud 86 extends over 50% of the uppermost portion of the width W. The shroud 86 acts to direct the impingement air flow 24 downward through the fins 64,66 and their louvers 80 to the lowermost portion of the fins 64,66 before the air flow 24 can exit radially and/or axially from the fins 64,66.

The fins 26,64,66 can be made from any suitable heat conductive material, such as for example, copper or aluminum. Preferably, the fin 26 is bonded, such as by brazing or soldering, to the surface 20 of the base plate 16. Preferably, the peaks 68 and valleys 70 of the fins 64 and 66 are bonded, such as by brazing or soldering, to the associated surfaces of the conductive post 62, separator sheet 84, and shroud 86.

While the axes 29 and 40 have been shown as parallel and aligned, it should be appreciated that in some applications it may be desirable for the axes 29 and 40 not be parallel and/or not to be aligned. Further, while the devices 10 and 60 have been described in connection with a pancake-type fan, other types of fans may prove more desirable in some applications.

1. An improvement in a heat sink device for cooling an electronic component having a surface that rejects heat, the heat sink device comprising a fan overlying said surface to direct an airflow towards said surface, said fan having a rotational axis, the improvement comprising:
a fin wound about a central axis, said central axis extending parallel to said rotational axis, said fin comprising louvered surfaces that extend parallel to said central axis.

2. The improvement of claim 1 further comprising:
a plate having first and second surfaces, the first surface configured to receive heat rejected from the surface of the electronic component, the second surface underlying the fan; and
a spiral wound fin on the second surface of said plate and underlying the fan, the fin comprising a strip of metal coiled about said central axis, said strip having said louvers formed therein extending parallel to said central axis between spaced side margins of said strip.

3. The improvement of claim 1 further comprising:
an elongate conductive post comprising first and second end surfaces and a circumferential surface extending between the end surfaces parallel to said central axis, the first end surface configured to receive heat rejected from the surface of the electronic component; and
at least one serpentine fin wrapped around said circumferential surface and having alternating peaks and valleys joined by louvered side walls, each of the peaks and valleys extending parallel to said central axis.

4. A heat sink device for cooling an electronic component having a surface that rejects heat, the device comprising:
a plate having first and second surfaces, the first surface configured to receive heat rejected from the surface of the electronic component;
a spiral wound fin on the second surface of said plate, the fin comprising a strip of metal coiled about an axis extending generally perpendicular to the second surface, said strip having louvers formed therein extending parallel to said axis between spaced side margins of said strip.

5. The device of claim 4 wherein each of said louvers has a louver angle, and the louver angles vary as a function of a radial distance from said axis.

6. The device of claim 4 wherein at least one of said side margins includes a plurality of spaced tabs, each of said tabs extending from said strip to engage an adjacent portion of said at least one of said side margins to maintain a desired spacing between adjacent coils of said spiral wound strip.

7. The device of claims 6 wherein each of said tabs extends in a radially outward direction from said strip.

8. The device of claim 4 further comprising a wire coiled about said axis and sandwiched between adjacent coils of said strip to maintain a desired spacing between said adjacent coils.

9. The device of claim 8 wherein said wire is sandwiched between louvers of adjacent coils of said strip.

10. The device of claim 4 wherein said strip has a width extending parallel to said louvers and said louvers extending over 80% to 95% of said width.

11. The device of claim 10 wherein said louvers extend over 88% to 93% of said width.

12. An improvement in a heat sink device for cooling an electronic component having a surface that rejects heat, the heat sink device comprising a plate having first and second surfaces, the first surface configured to receive heat rejected from the surface of the electronic component, and a fan overlying the second surface to direct an airflow towards the second surface, the improvement comprising:
a spiral wound fin on the second surface of said plate, the fin comprising a strip of metal coiled about an axis extending perpendicular to the second surface, said strip having louvers formed therein extending parallel to said axis between spaced side margins of said strip, each of said louvers having a louver angle that opens radially outward in a direction of rotation of the fan.

13. The improvement of claim 12 wherein the louver angles vary as a function of a radial distance from said axis.

14. The improvement of claim 12 wherein at least one of said side margins includes a plurality of spaced tabs, each of said tabs extending from said strip to engage an adjacent portion of said at least one of said side margins to maintain a desired spacing between adjacent coils of said spiral wound strip.

15. The improvement of claims 14 wherein each of said tabs extends in a radially outward direction from said strip.

16. The improvement of claim 12 further comprising a wire coiled about said axis and sandwiched between adjacent coils of said strip to maintain a desired spacing between said adjacent coils.

17. The improvement of claim 16 wherein said wire is sandwiched between louvers of adjacent coils of said strip.

18. The improvement of claim 12 wherein said strip has a width extending parallel to said louvers and said louvers extending over 80% to 95% of said width.

19. The improvement of claim 10 wherein said louvers extend over 88% to 93% of said width.

20. A heat sink device for transferring heat from an electronic component to a cooling airflow provided by a fan, the electronic component having a surface that rejects heat, the heat sink device comprising:
an elongate conductive post comprising first and second end surfaces and a circumferential surface extending between the end surfaces in a direction of elongation of the conductive post, the first end surface configured to receive heat rejected from the surface of the electronic component; and
at least one serpentine fin wrapped around said circumferential surface and having alternating peaks and valleys joined by louvered side walls, each of the peaks and valleys extending parallel to the direction of elongation.

21. The device of claims 20 wherein each of said louvers extends perpendicular to the direction of elongation.

22. The device of claim 20 wherein said at least one serpentine fin has a width extending parallel to said direction of elongation; and
further comprising a shroud covering a radially outermost portion of said at least one serpentine fin and extending over 30% to 60% of said width farthest from said first end surface.

23. The device of claim 22 wherein said shroud comprises a band.

24. The device of claim 20 further comprising:
a second serpentine fin wrapped around said circumferential surface between said circumferential surface and said at least one serpentine fin, and having alternating peaks and valleys extending parallel to the direction of elongation and joined by louvered side walls; and
a separating band sandwiched between second serpentine fin and said at least one serpentine fin.

25. The device of claim 24 wherein said separating band is perforated.

26. The device of claim 24 wherein said at least one serpentine fin has a width extending parallel to said direction of elongation; and
further comprising a shroud covering a radially outermost portion of said at least one serpentine fin and extending over 30% to 60% of said width farthest from said first end surface.

27. The device of claim 26 wherein said shroud comprises a band.

28. The device of claim 20 wherein said circumferential surface is cylindrical in shape.
